(19) United States
(12) Patent Application Publication
(10) Pub. No.: US 2010/0159217 A1
(43) Pub. Date: Jun. 24, 2010

(54) NEGATIVE-TYPE PHOTOSENSITIVE RESIN COMPOSITION, METHOD FOR FORMING PATTERNS, AND ELECTRONIC PARTS

(75) Inventor: Tomonori Minegishi, Ibaraki (JP)

Correspondence Address: GRIFFIN & SZIPL, PC, SUITE PH-1, 2300 NINTH STREET, SOUTH, ARLINGTON, VA, 22204, US

(73) Assignee: HITACHI CHEMICAL DUPONT MICROSYSTEMS, LTD, Tokyo (JP)

(21) Appl. No.: 12/305,668

(22) PCT Filed: Jun. 20, 2006
(86) PCT No.: PCT/JP2006/312358

§ 371 Date: Dec. 19, 2008

(51) Int. Cl. B32B 3/10; G03F 7/004; G03F 7/20

(52) U.S. Cl. 428/201; 430/270.1; 430/325; 428/195.1

(57) ABSTRACT

A heat resistant negative-type photosensitive resin composition which is good in sensitivity and resolution, a method for producing a pattern capable of obtaining the pattern which is excellent in sensitivity, resolution and heat resistance and has a good shape, and a highly reliable electronic part having the pattern having a good shape and property are provided. A crosslinking agent capable of crosslinking or polymerizing by an action of an acid includes a compound having at least one methylol group or alkoxyalkyl group in a molecule, in the negative-type photosensitive resin composition.

This is a National Phase Application in the United States of International Patent Application No. PCT/JP2006/312358 filed Jun. 20, 2006, which claims priority on Japanese application no. 2004-369247, filed Dec. 21, 2004. The entire disclosures of the above patent applications are hereby incorporated by reference.

### TECHNICAL FIELD

The present invention relates to a negative-type photosensitive resin composition containing a heat resistant polymer having a photosensitivity, and a method for forming patterns, and electronic parts, by the use thereof.

### BACKGROUND ART

Conventionally, polyimide resins having an excellent heat resistance as well as an electric property/mechanical property have been used for surface protection films and interlayer insulation films of semiconductor elements. However, the semiconductor elements have been highly integrated and grown in size in recent years, it has been required to thin and downsize sealing resin packages, and modes of surface mounting by LOC (lead-on-chip) and solder reflow have been taken. Thus, the polyimide resins which are more excellent in mechanical property and heat resistance have been required.

Meanwhile, photosensitive polyimide obtained by imparting a photosensitive property to polyimide has been used. When this is used, a process for forming the pattern can be simplified and the complicated process can be shortened. Heat resistant photoresists using conventional photosensitive polyimide or precursors thereof, and the use thereof are well-known. For a negative type, a method of introducing a methacryloyl group to a polyimide precursor through an ester bond or an ion bond (e.g., see Patent Documents 1 to 4), soluble polyimide having photopolymerizable olefin (e.g., see Patent Documents 5 to 10) and self-sensitized type polyimide having a benzophenone skeleton and having an alkyl group at ortho-position of an aromatic ring to which a nitrogen atom is bound (e.g., see Patent Documents 11 and 12) are available.

In the above negative types, an organic solvent such as N-methylpyrrolidone is required upon development. Thus, positive-type photosensitive resins which can be developed in an alkaline aqueous solution have been proposed recently. For the positive types, the method of introducing an o-nitrobenzyl group into the polyimide precursor through the ester bond (e.g., see Nonpatent Literature 1), the method of mixing a naphthoquinone diazide compound with soluble hydroxylimide or a polyoxazole precursor (e.g., see patent Documents 13 and 14), the method of introducing naphthoquinone diazide into soluble polyimide through the ester bond (e.g., Nonpatent Literature 2), and those obtained by mixing naphthoquinone diazide with the polyimide precursor (e.g., see Patent Document 15) are available.

However, the above negative types have problems in functions and resolution, and bring the reduction of yields upon production depending on their uses. In the above ones, a structure of the polymer to be used is limited. Thus, physical properties of finally obtained coatings are limited, and they are not suitable for multipurpose uses. Meanwhile, also in the positive types, by the problems with an absorption wavelength of a photosensitizing agent, a sensitivity or the resolution is low, and the structure is limited. Thus there are the similar problems.

Those obtained by mixing a diazonaphthoquinone compound with a polybenzoxazole precursor (e.g., see Patent Document 16), and those obtained by introducing a phenolic hydroxyl group in place of carboxylic acid, e.g., those obtained by introducing a phenol site into polyamide acid through the ester bond (e.g., see Patent Document 17) are available. However, these are insufficient in development property. Thus, film thickness loss in an unexposed portion and delamination of the resin from a substrate occur. For the purpose of improving such a development property and adhesion, those obtained by mixing polyamide acid having a siloxane moiety in a polymer skeleton (e.g., see Patent Documents 18 and 19) have been proposed. However, because of using polyamide acid as described above, a storage stability worsens. In addition, for the purpose of improving the storage stability and the adhesion, those where an amine terminal group is sealed with a polymerizable group (e.g., see patent Documents 20 to 22) have been proposed. However, these are low sensitive because of using a diazoquinone compound containing multiple aromatic rings as an acid generator, and these remarkably reduce a mechanical physical property after thermal cure because an amount of the diazoquinone compound to be added must be increased. Thus, it is hard to say that these are materials at practical levels.

### Patent Document 1: Japanese Patent Application Laid-Open No. 49-115541

### Patent Document 2: Japanese Patent Application Laid-Open No. 51-40922

### Patent Document 3: Japanese Patent Application Laid-Open No. 54-145794

### Patent Document 4: Japanese Patent Application Laid-Open No. 56-38038

### Patent Document 5: Japanese Patent Application Laid-Open No. 59-108031

### Patent Document 6: Japanese Patent Application Laid-Open No. 59-220730

### Patent Document 7: Japanese Patent Application Laid-Open No. 59-232122

### Patent Document 8: Japanese Patent Application Laid-Open No. 60-6729

### Patent Document 9: Japanese Patent Application Laid-Open No. 60-72925

### Patent Document 10: Japanese Patent Application Laid-Open No. 61-57620

### Patent Document 11: Japanese Patent Application Laid-Open No. 59-219330

### Patent Document 12: Japanese Patent Application Laid-Open No. 59-231533

### Patent Document 13: Japanese Patent Application Laid-Open Publication No. 64-60630

Patent Document 14: U.S. Pat. No. 4,395,482

### Patent Document 15: Japanese Patent Application Laid-Open No. 52-13315

### Patent Document 16: Japanese Patent Application Laid-Open Publication No. 1-46862

### Patent Document 17: Japanese Patent Application Laid-Open No. 10-307393

### Patent Document 18: Japanese Patent Application Laid-Open No. 4-31861

### Patent Document 19: Japanese Patent Application Laid-Open No. 4-46345

### Patent Document 20: Japanese Patent Application Laid-Open No. 5-197153

### Patent Document 21: Japanese Patent Application Laid-Open No. 9-183846

### Patent Document 22: Japanese Patent Application Laid-Open No. 2001-183835

### Patent Document 23: Japanese Patent Application Laid-Open No. 3-763

### Patent Document 24: Japanese Patent Application Laid-Open No. 7-219228

### Patent Document 25: Japanese Patent Application Laid-Open No. 10-186664

### Patent Document 26: Japanese Patent Application Laid-Open No. 11-202489

### Patent Document 27: Japanese Patent Application Laid-Open No. 2001-56559

### Patent Document 28: Japanese Patent Application Laid-Open No. 2001-194791

### Patent Document 29: Japanese Patent Application Laid-Open Hyo 2002-526793

Patent Document 30: U.S. Pat. No. 6,143,467

### Patent Document 31: Japanese Patent Application Laid-Open No. 2001-125267

Nonpatent Literature 1: J. Macromol. Sci. Chem., A24, 12, 1407, 1987

### Nonpatent Literature 2: Macromolecules, 23, 1990

### DISCLOSURE OF INVENTION

### Problem to be Solved by the Invention

Those where various chemical amplification systems are applied for the purpose of improving the problems of the above diazoquinone compounds have been also proposed. These may include chemical amplification type polyimide (e.g., see patent Document 23), chemical amplification type polyimide or a polybenzoxazole precursor (e.g., see patent Documents 24 to 30). Among them, those having the high sensitivity reduce a film property due to their low molecular weights, and those excellent in film property reduce the sensitivity due to insufficient solubility caused by their high molecular weights. It is hard to say that any of them are at practical levels. Those which utilize the negative type chemical amplification system utilizing a crosslinking reaction which progresses in the presence of a catalyst (e.g., see patent Documents 17 and 31) have been also proposed. However, the hydroxyl group is a crosslinking point in their molecular chains, a crosslinking efficiency is actually low, and these are not highly sensitive. Therefore, it is an actual circumstance that any of them is not enough at the practical level.

The present invention has been made for solving the above conventional problems, and provides a heat resistant negative-type photosensitive resin composition which is also good in sensitivity and resolution.

The present invention also provides a method for forming a pattern, by which a good shaped pattern which is excellent in sensitivity, resolution and heat resistance is obtained by the use of the above composition. The present invention also provides highly reliable electronic parts by having the pattern having the good shape and property.

### Means for Solving Problem

That is, the negative-type photosensitive resin composition according to the present invention is a negative-type photosensitive resin composition including (a) a heat resistant polymer, (b) a compound which generates an acid by irradiating active light and (c) a crosslinking agent capable of crosslinking or polymerizing by an action of the acid, wherein the crosslinking agent (c) capable of crosslinking or polymerizing by the action of the acid includes a compound having at least one methylol group or alkoxyalkyl group in a molecule.

In the negative-type photosensitive resin composition according to the present invention, the crosslinking agent (c) capable of crosslinking or polymerizing by the action of the acid is a compound represented by a general formula (I):

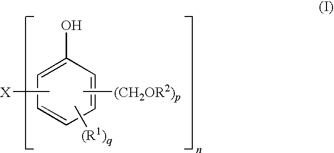

wherein, X represents a single bond or a monovalent to tetravalent organic group, R¹ and R² each independently represent a hydrogen atom or a monovalent organic group, n represents an integer of 1 to 4, and p and q are each independently an integer of 0 to 4.

In the negative-type photosensitive resin composition according to the present invention, the crosslinking agent (c) which can crosslink or polymerize by the action of the acid is a compound represented by the general formula (II):

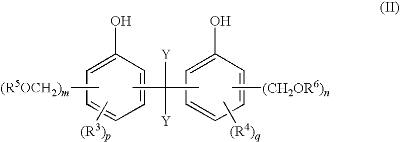

wherein, two Y each independently represent a hydrogen atom or an alkyl group having 1 to 10 carbon atoms and may include an oxygen atom or a fluorine atom, R³ to R⁶ each independently represent a hydrogen atom or a monovalent organic group, m and n each independently represent an integer of 1 to 3, and p and q each independently represent an integer of 0 to 4.

In the negative-type photosensitive resin composition according to the present invention, the crosslinking agent (c) which can crosslink or polymerize by the action of the acid is a compound represented by the general formula (III):

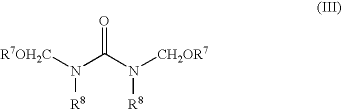

wherein, R⁷ and R⁸ each independently represent a hydrogen atom or a monovalent organic group.

In the negative-type photosensitive resin composition according to the present invention, the heat resistant polymer (a) is polyimide, polyoxazole or a precursor thereof.

The method for forming the pattern according to the present invention includes a step of applying and drying the above negative-type photosensitive resin composition on a support substrate, a step of exposing a photosensitive resin film obtained from the step of drying, a step of heating the photosensitive resin film after the exposure, a step of developing the photosensitive resin film after the heating using an alkaline aqueous solution, and a step of thermally treating the photosensitive resin film after the development.

The electronic parts according to the present invention are electronic parts having an electronic device having a layer of the pattern obtained by the above method for forming the pattern, and the layer of the above pattern is provided as an interlayer insulation film layer and/or a surface protection film layer in the electronic device.

### EFFECT OF THE INVENTION

The negative-type photosensitive resin composition according to the present invention is excellent in sensitivity, resolution and heat resistance.

Also according to the method for forming the pattern according to the present invention, the pattern which is excellent in sensitivity, resolution and heat resistance and has the good shape is obtained by the use of the composition.

Furthermore, the electronic parts according to the present invention is highly reliable by having the pattern having the good shape and property.

### BRIEF DESCRIPTION OF DRAWINGS

FIG. 1 is a view showing a process of producing a semiconductor apparatus of a multilayer wiring structure.

EXPLANATIONS OF LETTERS OR NUMERALS

| | |
|---|---|
| 1 | Semiconductor substrate |
| 2 | Protection film |
| 3 | First conductor layer |
| 4 | Interlayer insulation film layer |
| 5 | Photosensitive resin layer |
| 6A, 6B, 6C | Window |
| 7 | Second conductor layer |
| 8 | Surface protection layer |

### BEST MODES FOR CARRYING OUT THE INVENTION

An embodiment of the negative-type photosensitive resin composition, the method for forming the pattern and the electronic parts according to the present invention will be described in detail based on the drawing. The present invention is not limited to the embodiment.

[Negative-Type Photosensitive Resin Composition]

The negative-type photosensitive resin composition according to the present invention includes (a) a heat resistant polymer, (b) a compound which generates an acid by irradiating active light and (c) a compound which can crosslink or polymerize by an action of the acid and has at least one methylol group or alkoxyalkyl group in a molecule.

This constitution can significantly respond even if the heat resistant polymer which imparts the photosensitivity has any structure, and can provide the heat resistant negative-type photosensitive resin composition which is also good in sensitivity and resolution.

The heat resistant polymer (a) in the present invention is not particularly limited structurally. Polyimide, polyoxazole and polymer compounds known as precursors thereof are preferable in terms of workability and heat resistance. A copolymer or a mixture of two or more thereof can be used.

A molecular weight of a component (a) which is the heat resistant polymer is preferably 3,000 to 200,000, and more preferably 5,000 to 100,000 as a weight average molecular weight. Here, the molecular weight is measured by gel permeation chromatography and obtained by converting from a standard curve of standard polystyrene.

An amount of the compound which generates the acid by irradiating the active light (hereinafter referred to as an acid generator), used as the component (b) in the composition of the present invention is preferably 0.01 to 50 parts by weight, more preferably 0.01 to 20 parts by weight, and still more preferably 0.5 to 20 parts by weight based on 100 parts by weight of the component (a), for making the sensitivity and the resolution good upon the exposure.

The acid generator (b) which is the compound which generates the acid by irradiating the active light used for the present invention exhibits an acidity by irradiating the active light such as ultraviolet light as well as has the action to crosslink the component (c) with the polyamide derivative which is the component (a) or polymerize the components (c) one another. As such a compound of the component (b), specifically diaryl sulfonium salts, triaryl sulfonium salts, dialkylphenacyl sulfonium salts, diaryl iodonium salts, aryl diazonium salts, aromatic tetracarboxylate ester, aromatic sulfonate ester, nitrobenzyl ester, oxime sulfonate ester, aromatic N-oxyimidesulfonate, aromatic sulfamide, haloalkyl group-containing hydrocarbon based compounds, haloalkyl group-containing heterocyclic compounds and naphthoquinone diazide-4-sulfonate ester are used. Such compounds can be used in combination of two or more or in combination with the other sensitizer if necessary. Among them, aromatic oxime sulfonate ester and aromatic N-oxyimidesulfonate are preferable because an effect can be expected in terms of high sensitivity.

The crosslinking agent (c) capable of crosslinking or polymerizing by the action of the acid, used for the present invention is not particularly limited, except for having at least one methylol group or alkoxyalkyl group in the molecule, but the compounds having two or more methylol groups or alkoxyalkyl groups in the molecule, which are bound to a benzene ring, or melamine resins and urea resins substituted with the methylol group and/or alkoxyalkyl group at position N are preferable. These compounds which can be used in the present invention are not particularly limited, but among them, those represented by the following general formula (I) or (III) are preferable because they are excellent in balance of the effect to prevent melting of an exposed portion upon curing and a cured film property. In particular, those represented by the following general formula (I) have the effect to enhance the mechanical property of the cured film, and those represented by the following general formula (III) are excellent in sensitivity.

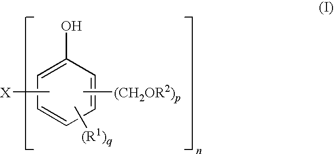

In the formula, X represents a single bond or a monovalent to tetravalent organic group, R¹ and R² each independently represent a hydrogen atom or a monovalent organic group, n represents an integer of 1 to 4, and p and q each independently represent an integer of 0 to 4.

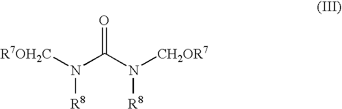

In the formula, R⁷ and R⁸ each independently represent a hydrogen atom or a monovalent organic group.

The organic group represented by X in the general formula (I) may include alkylene groups such as methylene group, ethylene group and propylene group having 1 to 10 carbon atoms, alkylidene groups such as ethylidene group having 2 to 10 carbon atoms, arylene groups such as phenylene group having 6 to 30 carbon atoms, groups obtained by substituting a part or all of hydrogen atoms of these hydrocarbons with halogen atoms such as fluorine atoms, a sulfone group, a carbonyl group, an ether bond, a thioether bond and an amide bond.

Also, bivalent organic groups represented by the following general formula (IV):

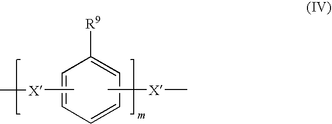

wherein X′ are each independently selected from a single bond, an alkylene group (e.g., having 1 to 10 carbon atoms), an alkylidene group (e.g., having 2 to 10 carbon atoms), groups obtained by substituting a part or all of hydrogen atoms in them with halogen atoms, a sulfone group, an ether bond, a thioether bond and an amide bond, R⁹ represents a hydrogen atom, hydroxyl group, alkyl group or haloalkyl group, when multiple R⁹ are present, they may be the same or different, and m represents an integer of 1 to 10, may be included as preferable ones. Furthermore, those represented by the following general formula (II):

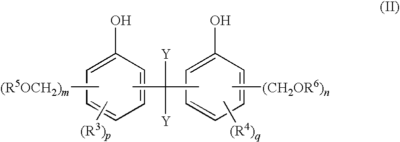

wherein two Y each independently represent a hydrogen atom or an alkyl group having 1 to 10 carbon atoms and may include an oxygen atom or a fluorine atom, R³ to R⁶ each independently represent a hydrogen atom or a monovalent organic group, m and n each independently represent an integer of 1 to 3, and p and q each independently represent an integer of 0 to 4, may be included as particularly preferable ones because they are also excellent in sensitivity and resolution.

Specifically, those containing an oxygen atom as Y are alkyloxy groups and the like, and those containing fluorine atoms as Y are perfluoroalkyl groups and the like. The organic groups of R⁵ and R⁶ may include specifically methyl group, ethyl group, n-propyl group, isopropyl group, n-butyl group, tert-butyl group, and amyl group are exemplified as typical examples, but are not limited thereto. In the general formulae (I) and (II), those represented by the following chemical formulae (V) may be included.

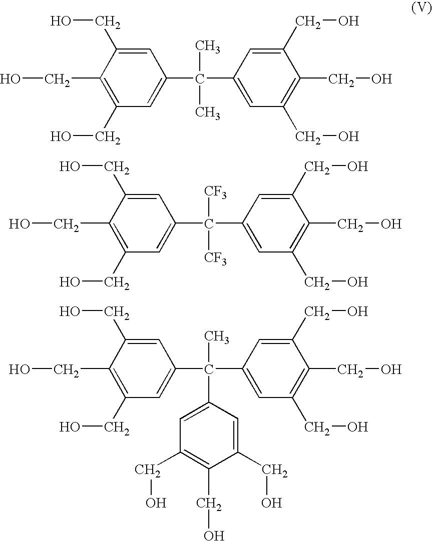

In the general formula (III), more preferable ones in terms of sensitivity may include those represented by the following formulae (VI):

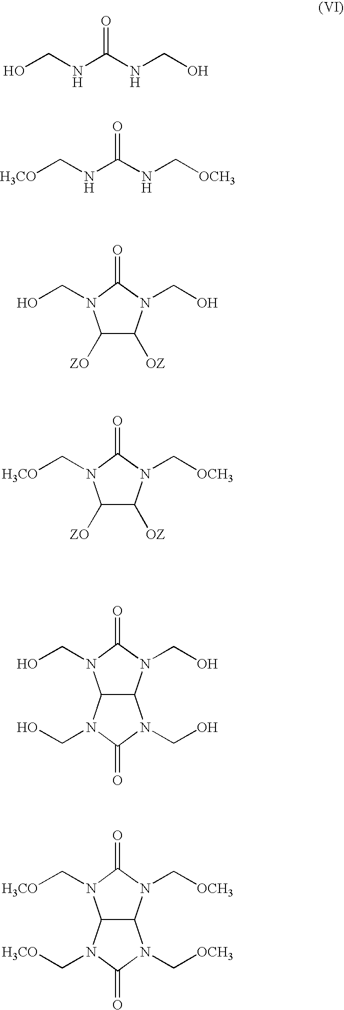

wherein, Z represents a monovalent alkyl group having 1 to 10 carbon atoms.

The amount of the component (c) which is the crosslinking agent used for the present invention is preferably 0.1 to 50 parts by weight, more preferably 0.1 to 20 parts by weight, and still more preferably 0.5 to 20 parts by weight based on 100 parts by weight of the component (a) in terms of sensitivity and resolution upon the exposure and for preventing the melting of the pattern upon the cure.

The negative-type photosensitive resin composition according to the present invention can contain organic silane compounds and aluminium chelate compounds for enhancing adhesiveness of the cured film with the substrate. Examples of the organic silane compound may include vinyl triethoxysilane, γ-glycidoxypropyl triethoxysilane, γ-methacryloxypropyl trimethoxysilane, urea propyl triethoxysilane, methylphenyl silanediol, ethylphenyl silanediol, n-propylphenyl silanediol, isopropylphenyl silanediol, n-butylphenyl silanediol, isobutylphenyl silanediol, tert-butylphenyl silanediol, diphenyl silanediol, ethylmethylphenyl silanol, n-propylmethylphenyl silanol, isopropylmethylphenyl silanol, n-butylmethylphenyl silanol, isobutylmethylphenyl silanol, tert-butylmethylphenyl silanol, ethyl n-propylphenyl silanol, ethylisopropylphenyl silanol, n-butylethylphenyl silanol, isobutylethylphenyl silanol, tert-butylethylphenyl silanol, methyldiphenyl silanol, ethyldiphenyl silanol, n-propyldiphenyl silanol, isopropyldiphenyl silanol, n-butyldiphenyl silanol, isobutyldiphenyl silanol, tert-butyldiphenyl silanol, phenyl silanetriol, 1,4-bis(trihydroxysilyl)benzene, 1,4-bis(methyldihydroxysilyl)benzene, 1,4-bis(ethyldihydroxysilyl)benzene, 1,4-bis(propyldihydroxysilyl)benzene, 1,4-bis(butyldihydroxysilyl)benzene, 1,4-bis(dimethylhydroxysilyl)benzene, 1,4-bis(diethylhydroxysilyl)benzene, 1,4-bis(dipropylhydroxysilyl)benzene, 1,4-bis(dibutylhydroxysilyl)benzene, and the like. Examples of the aluminium chelate compound may include tris(acetylacetonate) aluminium, acetyl acetate aluminium diisopropylate, and the like. When these adhesive-imparting agents are used, their amount is preferably 0.1 to 20 parts by weight, and more preferably 0.5 to 10 parts by weight based on 100 parts by weight of the component (a).

In the negative-type photosensitive resin composition of the present invention, an appropriate surfactant or leveling agent can be added for enhancing an application property, e.g., preventing a striation (unevenness of film thickness) or enhancing the development property. As such a surfactant or leveling agent, for example, polyoxyethylene uraryl ether, polyoxyethylene stearyl ether, polyoxyethylene oleyl ether, polyoxyethylene octylphenol ether, and the like are available. Commercially available ones may include Magafax F171, F173, R-08 (product names supplied from Dainippon Ink And Chemicals, Incorporated), Florard FC430, FC431 (product names supplied from Sumitomo 3M Ltd.), organosiloxane polymers KP341, KBM303, KBM 403, KBM803 (product names supplied from Shin-Etsu Chemical Co., Ltd.), and the like.

In the present invention, these components are dissolved in a solvent and made into a varnish form to use. As the solvent, N-methyl-2-pyrrolidone, γ-butylolactone, N,N-dimethylacetamide, dimethylsulfoxide, 2-methoxyethanol, diethylene glycol diethyl ether, diethylene glycol dibutyl ether, propylene glycol monomethyl ether, dipropylene glycol monomethyl ether, propylene glycol monomethyl ether acetate, methyl lactate, ethyl lactate, butyl lactate, methyl-1,3-butylene glycol acetate, 1,3-butylene glycol acetate, cyclohexane, cyclopentanone, tetrahydrofuran, and the like are available, and may be used alone or in mixture.

[Method for Forming Pattern]

Subsequently, the method for forming the pattern according to the present invention will be described. The method for forming the pattern according to the present invention includes a step of applying and drying the above negative-type photosensitive resin composition on a support substrate, a step of exposing, a step of heating the photosensitive resin film after the exposure, a step of developing the photosensitive resin film after the heating using an alkaline aqueous solution, and a step of thermally treating the photosensitive resin film after the development. Through these steps, it is possible to make the pattern of the desired heat resistant polymer.

In the step of applying and drying on the support substrate, this photosensitive resin composition is applied with rotation on the support substrate such as a glass substrate, a semiconductor, a metal oxide insulator (e.g., TiO₂, SiO₂) or silicon nitride using a spinner, and subsequently dried using a hotplate or an oven.

Then, in the exposure step, the active light such as ultraviolet light, visible light or radiation ray is irradiated to the photosensitive resin composition which has become a coating on the support substrate through a mask. In the development step, the pattern is obtained by removing an exposed portion with a developing solution. Examples of the developing solution may include alkaline aqueous solutions such as aqueous solutions of sodium hydroxide, potassium hydroxide, sodium silicate, ammonia, ethylamine, diethylamine, triethylamine, triethanolamine and tetramethylammonium hydroxide as preferable ones. A base concentration in these aqueous solutions is preferably 0.1 to 10% by weight. Alcohols and the surfactants can be further added to the above developing solution to use. These can each be contained in the range of preferably 0.01 to 10 parts by weight and more preferably 0.1 to 5 parts by weight based on 100 parts by weight of the developing solution.

Then, in the thermal treatment step, the pattern of the heat resistant polymer having an imide ring, an oxazole ring and the other functional group is made by treating the obtained pattern with heat preferably at 150 to 450° C. Microwave can also be used for the thermal treatment. When the microwave is irradiated in pulse with changing a frequency, stationary wave can be prevented. Thus, the microwave is preferable because it can evenly heat the substrate surface. Furthermore, when the substrate contains a metal wiring like the electronic parts, if the microwave is irradiated in pulse with changing the frequency, the occurrence of electric discharge or the like from the metal can be prevented. Thus, the microwave is preferable because the electronic parts can be protected from being broken.

In the negative-type photosensitive resin composition according to the present invention, when polyamide acid and polyhydroxyamide are dehydrated and ring-closed to make polyimide and polyoxazole, respectively, the frequency of the microwave to be irradiated is in the range of 0.5 to 20 GHz, and practically 1 to 10 GHz, and more preferably 2 to 9 GHz.

It is desirable to continuously change the frequency of the microwave to be irradiated, but actually, the microwave is irradiated by changing the frequency in a staircase pattern. At that time, the shorter a time period for which the microwave with a single frequency is irradiated is, the stationary wave and the electric discharge from the metal hardly occur, and the time period is preferably one millisecond or less and particularly preferably 100 microseconds or less.

An output power of the microwave to be irradiated varies depending on the size of an apparatus and the amount of the material to be heated, and is generally in the range of 10 to 2,000 W, in practical use, is more preferably 100 to 1,000 W, still more preferably 100 to 700 W and most preferably 100 to 500 W. When the output power is 10 W or less, it is difficult to heat the material to be heated in a short time period. When it is 2,000 W or more, rapid elevation of the temperature easily occurs.

It is preferable that the microwave irradiated when polyamide acid and polyhydroxyamide are dehydrated and ring-closed to make polyimide and polyoxazole, respectively in the negative-type photosensitive resin composition according to the present invention is turned on/off in pulse. This is preferable because by irradiating the microwave in pulse, it is possible to keep the set heating temperature and avoid the damage to a polyoxazole thin film and the substrate. The time period for which the microwave in pulse is irradiated once varies depending on the condition, and is generally 10 seconds or less.

The time period for which polyamide acid and polyhydroxyamide are dehydrated and ring-closed to make polyimide and polyoxazole, respectively in the negative-type photosensitive resin composition according to the present invention is the time period until a dehydration and ring-closing reaction is sufficiently advanced, and is generally 5 hours or less in view of working efficiency. An atmosphere for the dehydration and ring-closing can be selected from either in atmospheric air or in an inert atmosphere such as nitrogen.

Thus, the microwave under the above condition is irradiated to the substrate having the negative-type photosensitive resin composition according to the present invention as the layer to dehydrate and ring-close polyamide acid and polyhydroxyamide in the negative-type photosensitive resin composition according to the present invention, thereby obtaining polyimide and polyoxazole which are not different in physical property from a dehydrated and ring-closed film obtained at high temperature using a thermodiffusion furnace, also by the dehydration and ring-closing process at low temperature using the microwave.

[Electronic Pars]

Subsequently, the electronic parts according to the present invention will be described. The negative-type photosensitive resin composition according to the present invention can be used for semiconductor apparatuses and the electronic parts such as multilayer wiring plates, and specifically can be used for forming surface protection films and interlayer insulation films of the semiconductor apparatus, the interlayer insulation films of the multilayer wiring plate, and the like. The electronic parts according to the present invention is not particularly limited, except for having the surface protection film or the interlayer insulation film formed using the above negative-type photosensitive resin composition, and can take various structures.

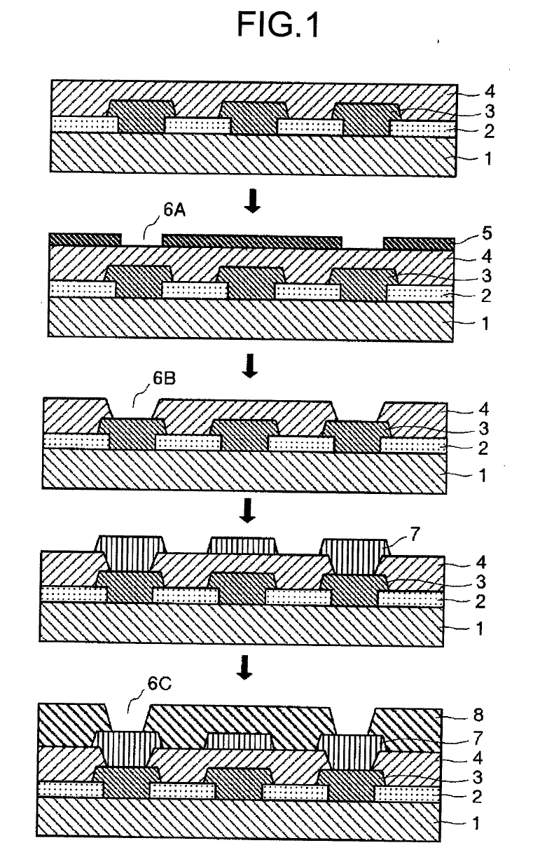

One example of the process for producing a semiconductor apparatus (electronic part) using the negative-type photosensitive resin composition according to the present invention will be described below. FIG. 1 is a view showing the process for producing the semiconductor apparatus having the multilayer wiring structure. In the figure, a semiconductor substrate 1 such as an Si substrate having circuit elements is covered with a protection film 2 such as a silicon oxide film except a predetermined portions of the circuit elements, and a first conductor layer 3 is formed on the exposed circuit elements. A film 4 of a polyimide resin as the interlayer insulation film is formed on the semiconductor substrate by a spin coating method (Step (a)).

Then, a chlorinated rubber based or phenol novolak based photosensitive resin layer 5 is formed on the interlayer insulation film 4 by the spin coating method, and windows 6A are provided by a publicly known photo-etching technology so that the interlayer insulation film at predetermined portion is exposed (Step (b)). The interlayer insulation film 4 exposed by the windows 6A is selectively etched by a dry etching procedure using a gas of oxygen or carbon tetrafluoride to open windows 6B. Then, the photosensitive resin layer 5 is completely removed using an etching solution which corrodes the photosensitive resin layer 5 only without corroding the first conductor layer 3 exposed from the windows 6B (Step (c)).

A second conductor layer 7 is further formed using the publicly known photo-etching technology, and an electric connection with the first conductor layer 3 is completely performed (Step (d)). When the multiple wiring structure having three layer or more is formed, the above steps can be repeated to form respective layers.

Subsequently, a surface protection film 8 is formed. In the example in this figure, this surface protection film is obtained as a heat resistant polymer film by applying the photosensitive resin composition by the spin coating method, drying it, irradiating the light thereto from above the mask in which the pattern to form the windows 6C at the predetermined portions has been depicted, then developing the film using the alkaline aqueous solution to form the pattern, and heating the film to make the heat resistant polymer film. This heat resistant polymer film protects the conductor layer from stress and a ray from the outside, and the resulting semiconductor apparatus is excellent in reliability. In the above example, it is also possible to form the interlayer insulation film using the negative-type photosensitive resin composition according to the present invention.

### EXAMPLES

### Examples 1 to 24

The present invention will be specifically described below with reference to the following Examples.

### Synthesis Example 1

### Synthesis of Polybenzoxazole Precursor

In a 0.5 liter flask equipped with a stirrer and a thermometer, 15.48 g (60 mmol) of 4,4′-diphenyl ether dicarboxylic acid and 90 g of N-methylpyrrolidone were placed, the flask was cooled to 5° C., then 23.9 g (120 mmol) of thionyl chloride was dropped, and the mixture was reacted for 30 minutes to yield a solution of 4,4′-diphenyl ether tetracarboxylic acid chloride. Then, in a 0.5 liter flask equipped with the stirrer and the thermometer, 87.5 g of N-methylpyrrolidone was placed, 18.30 g (50 mmol) of bis(3-amino-4-hydroxyphenyl)hexafluoropropane and 2.18 g (20 mmol) of m-aminophenol were added thereto and stirred and dissolved, subsequently 9.48 g (120 mmol) of pyridine was added, then a solution of 4,4′-diphenyl ether dicarboxylic acid chloride was dropped over 30 minutes with keeping the temperature at 0 to 5° C., and the mixture solution was continued to be stirred for 30 minutes. The solution was poured in 3 liters of water, a precipitate was collected, washed three times with purified water, and dried under reduced pressure to yield polyhydroxyamide (hereinafter referred to as Polymer I). A weight average molecular weight of Polymer I obtained by standard polystyrene conversion was 17,600, and a dispersivity was 1.6.

### Synthesis Example 2

Polyhydroxyamide was synthesized in the same way as in Synthesis Example 1, except that 50 mol % of 4,4′-diphenyl ether dicarboxylic acid used in Synthesis Example 1 was replaced with cyclohexane-1,4-dicarboxylic acid. The weight average molecular weight of resulting polyhydroxyamide (hereinafter referred to as Polymer II) obtained by standard polystyrene conversion was 18,580, and the dispersivity was 1.5.

### Synthesis Example 3

### Synthesis of Polyimide Precursor

In a 0.2 liter flask equipped with the stirrer and the thermometer, 10 g (32 mmol) of 3,3′,4,4′-diphenyl ether tetracarboxylic acid dianhydride (ODPA) and 3.87 g (65 mmol) of isopropyl alcohol were dissolved in 45 g of N-methylpyrrolidone, a catalytic amount of 1,8-diazabicycloundecene was added thereto, the mixture was heated at 60° C. for two hours and subsequently stirred under room temperature (25° C.) for 15 hours to esterify.

Subsequently, 7.61 g (64 mmol) of thionyl chloride was added under ice cooling, the temperature was back to the room temperature and the reaction was performed for 2 hours to yield a solution of acid chloride. Then, in a 0.5 liter flask equipped with the stirrer and the thermometer, 40 g of N-methylpyrrolidone was placed, 10.25 g (28 mmol) of bis(3-amino-4-hydroxyphenyl)hexafluoropropane and 0.87 g (8 mmol) of m-aminophenol were added thereto, the mixture was stirred and dissolved, subsequently 7.62 g (64 mmol) of pyridine was added thereto, the solution of acid chloride prepared previously was dropped over 30 minutes with keeping the temperature at 0 to 5° C., and the mixture solution was continued to be stirred for 30 minutes. This reaction solution was dropped into distilled water, a precipitate was collected by filtration and dried under reduced pressure to yield polyamic acid ester (hereinafter referred to as Polymer III).

Its weight average molecular weight was 19,400 and an esterification ratio obtained by NMR spectrum was 100%.

[Evaluation of Photosensitive Property]

The compound (b) which generates the acid by irradiating the active light and the crosslinking agent (c) in predetermined amounts shown in Table 1 were combined with 100 parts by weight of each of Polymer I to III.

The above solution was spin-coated on a silicon wafer to form a coating having a dry film thickness of 3 to 10 μm. Subsequently, the coating was exposed to i-ray (365 nm) using an ultrahigh pressure mercury lamp through an interference filter. After the exposure, the coating was heated at 120° C. for 3 minutes, and developed in an aqueous solution of 2.38% by weight of tetramethylammonium hydroxide until the silicon wafer in exposed portion appeared, followed by being rinsed with water. Then, a minimum exposure amount (sensitivity) required for forming the pattern having a residual film thickness ratio (ratio of film thickness before and after the development) of 90% or more, and a resolution were calculated. Their results were correctively shown in Table 2.

TABLE 1

| Item | Component (a) | Component (b) | Component (c) |
|---|---|---|---|
| Example 1 | Polymer-I | B1 (5) | C1 (5) |
| Example 2 | Polymer-I | B1 (5) | C1 (5) + C4 (5) |
| Example 3 | Polymer-I | B1 (5) | C2 (5) |
| Example 4 | Polymer-I | B1 (5) | C3 (5) |
| Example 5 | Polymer-I | B2 (5) | C3 (5) |
| Example 6 | Polymer-I | B1 (5) | C4 (5) |
| Example 7 | Polymer-I | B1 (5) | C5 (5) |
| Example 8 | Polymer-I | B2 (5) | C5 (5) |
| Example 9 | Polymer-I | B1 (5) | C5 (5) + C9 (5) |
| Example 10 | Polymer-I | B2 (5) | C6 (5) |
| Example 11 | Polymer-I | B1 (5) | C7 (5) |
| Example 12 | Polymer-I | B2 (5) | C8 (5) |
| Example 13 | Polymer-I | B1 (5) | C9 (5) |
| Example 14 | Polymer-I | B1 (5) | C6 (5) + C9 (5) |
| Example 15 | Polymer-I | B1 (5) | C10 (5) |
| Example 16 | Polymer-I | B2 (5) | C11 (5) |
| Example 17 | Polymer-II | B1 (5) | C1 (5) |
| Example 18 | Polymer-II | B1 (5) | C5 (5) |
| Example 19 | Polymer-II | B2 (5) | C3 (5) |
| Example 20 | Polymer-II | B2 (5) | C8 (5) |
| Example 21 | Polymer-III | B1 (5) | C2 (3) + C3 (5) |
| Example 22 | Polymer-III | B1 (5) | C4 (5) |
| Example 23 | Polymer-III | B1 (5) | C6 (5) |
| Example 24 | Polymer-III | B2 (5) | C9 (5) |

In the Table, numerical values in parentheses represent the added amounts as parts by weight based on 100 parts by weight of Polymer. In Table 1, B1 and B2 used as the component (b) and C1 to C11 used as the component (c) are the compounds represented by the following chemical formulae (VII) and (VIII), respectively.

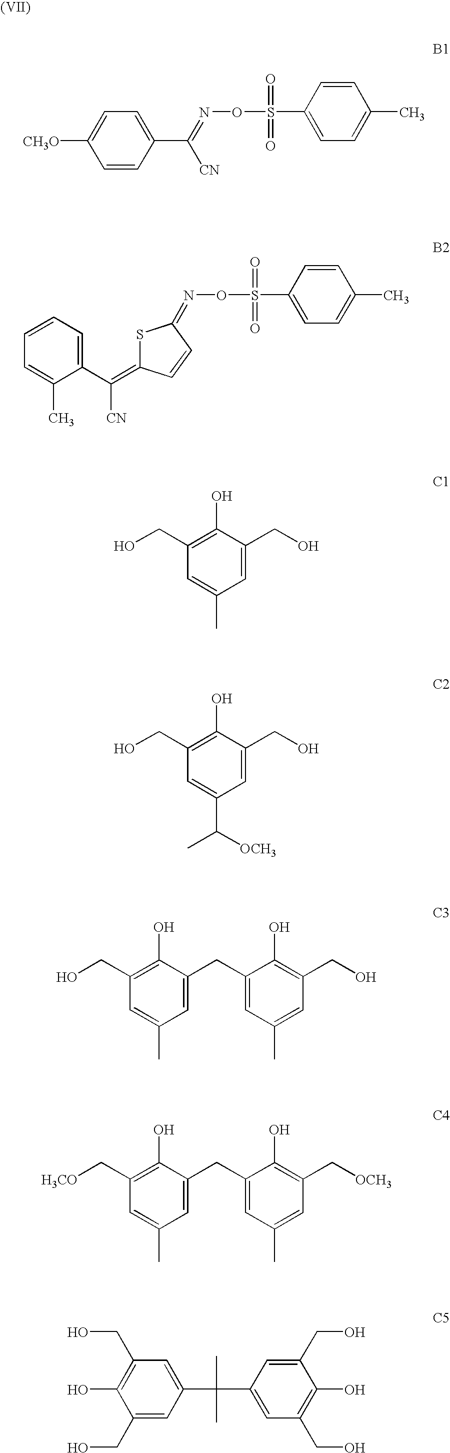

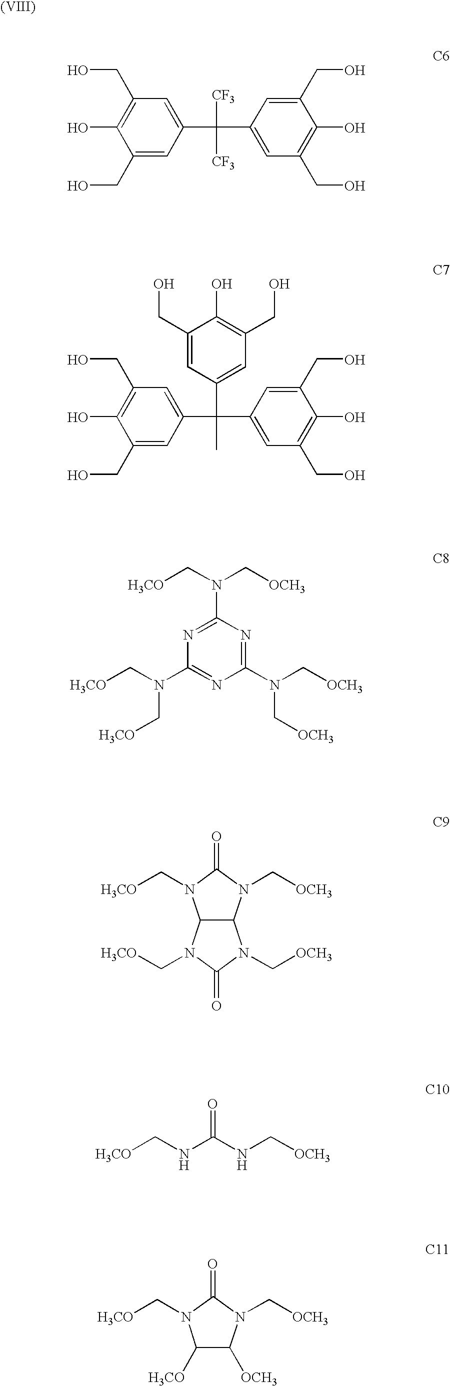

TABLE 2

| | Sensitivity | Resolution |
|---|---|---|
| Item | (mJ/cm²) | (μm) |
| Example 1 | 350 | 6 |
| Example 2 | 300 | 5 |
| Example 3 | 250 | 6 |
| Example 4 | 230 | 5 |
| Example 5 | 280 | 4 |
| Example 6 | 2250 | 5 |
| Example 7 | 150 | 4 |
| Example 8 | 170 | 4 |
| Example 9 | 130 | 4 |
| Example 10 | 300 | 4 |
| Example 11 | 380 | 6 |
| Example 12 | 450 | 5 |
| Example 13 | 150 | 5 |
| Example 14 | 150 | 4 |
| Example 15 | 430 | 6 |
| Example 16 | 300 | 6 |
| Example 17 | 270 | 6 |
| Example 18 | 110 | 5 |
| Example 19 | 240 | 4 |
| Example 20 | 300 | 5 |
| Example 21 | 230 | 5 |
| Example 22 | 210 | 4 |
| Example 23 | 260 | 5 |
| Example 24 | 240 | 3 |

The high sensitivity and the high resolution were obtained as the above.

### Examples 25 to 30

The materials used in Examples 1, 6, 7, 10, 13 and 21 shown in Table 1 were further examined by changing the curing method. The negative-type photosensitive resin composition solution was spin-coated on the silicon wafer and heated at 120° C. for 3 minutes to form the coating having the film thickness of 15 μm. Subsequently, the coating was cured for 2 hours to yield the cured film having the film thickness of 10 μm at a microwave output power of 450 W and a microwave frequency of 5.9 to 7.0 GHz with keeping a substrate temperature at 250° C. using Microcure 2100 supplied from Lambda Technology Corporation.

Subsequently, this cured film was peeled using an aqueous solution of hydrofluoric acid, washed with water and dried. Then, its glass transition temperature (Tg), an elongation and a temperature for 5% weight loss were measured. These results were shown in Table 3.

TABLE 3

| | Photosensitive | | Breaking | |
|---|---|---|---|---|
| | resin | Tg | elongation | Td |
| Item | composition | (° C.) | (%) | (° C.) |
| Example 25 | Materials in | 266 | 18 | 467 |
| | Example 1 | | | |
| Example 26 | Materials in | 270 | 20 | 473 |
| | Example 6 | | | |
| Example 27 | Materials in | 271 | 22 | 473 |
| | Example 7 | | | |
| Example 28 | Materials in | 279 | 18 | 471 |
| | Example 10 | | | |
| Example 29 | Materials in | 275 | 20 | 468 |
| | Example 13 | | | |
| Example 30 | Materials in | 278 | 17 | 473 |
| | Example 21 | | | |

As the above, even when the negative-type photosensitive resin composition according to the present invention is processed by the method of irradiating the microwave in pulse with keeping the substrate temperature at 250° C. and changing the frequency, satisfactory physical properties are obtained. It has been found that polyamide or polyimide is effectively dehydrated and ring-closed, and cured.

### Comparative Examples 1 to 7

The components (b) and (c) in predetermined amounts shown in Table 5 were combined with 100 parts by weight of Polymer, and the evaluation was performed in the same way as in Examples. These results were shown in Table 5. In both Comparative Examples 1 and 2, no insolubilization by crosslinking reaction or polymerization occurred in the exposed portions, and thus no pattern was obtained. In Comparative Examples 3 to 5, although negative images could be obtained, the residual film ratio was remarkably low compared with Examples and was not enhanced even when the exposure amount was increased. This indicated that the methylol group or the alkoxyalkyl group of the crosslinking agent component contributed to the enhancement of the photosensitive property.

TABLE 4

| Item | Component (a) | Component (b) | Component (c) |
|---|---|---|---|
| Comparative | Polymer-I | B1 (5) | None |
| Example 1 | | | |
| Comparative | Polymer-I | B1 (5) | C12 (5) |
| Example 2 | | | |
| Comparative | Polymer-I | B1 (5) | C13 (5) |
| Example 3 | | | |
| Comparative | Polymer-I | B1 (5) | C14 (5) |
| Example 4 | | | |
| Comparative | Polymer-I | B1 (5) | C14 (15) |
| Example 5 | | | |

In Table 4, B1 used as the component (b) is the same as in Table 1, and C12, 13 and 14 used as the component (c) are the compounds represented by the following chemical formulae (IX).

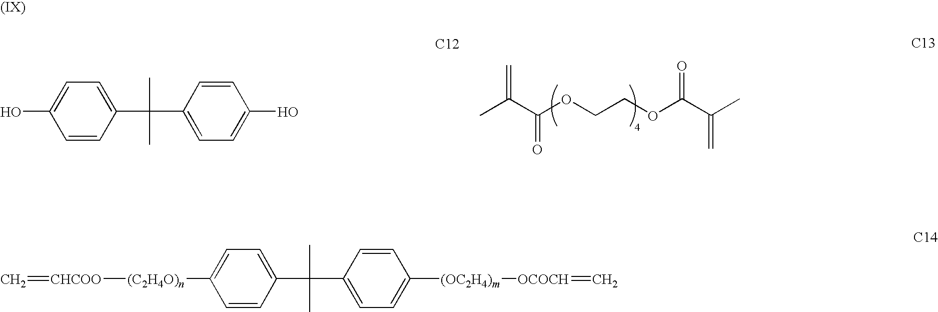

TABLE 5

| | | |
|---|---|---|
| | Sensitivity | Resolution |
| Item | (mJ/cm²) | (μm) |

| | |
|---|---|
| Comparative | No pattern was obtained. |
| Example 1 | |
| Comparative | |
| Example 2 | |
| Comparative | The residual film ratio in |
| Example 3 | exposed portion did not exceed 40 |
| Comparative | to 50%, and no good pattern was |
| Example 4 | obtained. |
| Comparative | |
| Example 5 | |

### INDUSTRIAL APPLICABILITY

As the above, the negative-type photosensitive resin composition according to the present invention is excellent in sensitivity, resolution and heat resistance. According to the method for forming the pattern of the present invention, the pattern which is excellent in sensitivity, resolution and heat resistance and has a good shape is obtained by the use of the composition. The electronic parts according to the present invention is highly reliable by having the pattern having the good shape and property. Therefore, the present invention is useful for the electronic parts in the electronic devices.

1. A negative-type photosensitive resin composition comprising:
(a) a heat resistant polymer;
(b) a compound which generates an acid by irradiating active light and
(c) a crosslinking agent capable of crosslinking or polymerizing by an action of the acid, wherein the crosslinking agent (c) capable of crosslinking or polymerizing by the action of the acid includes a compound having at least one methylol group or alkoxyalkyl group in a molecule.

2. The negative-type photosensitive resin composition according to claim 1, wherein the crosslinking agent (c) capable of crosslinking or polymerizing by the action of the acid is a compound represented by a general formula (I): 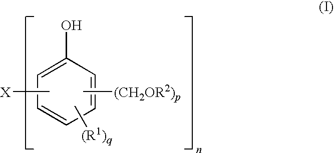
wherein, X represents a single bond or a monovalent to tetravalent organic group, R¹ and R² each independently represent a hydrogen atom or a monovalent organic group, n represents an integer of 1 to 4, and p and q each independently represent an integer of 0 to 4.

3. The negative-type photosensitive resin composition according to claim 2, wherein the crosslinking agent (c) capable of crosslinking or polymerizing by the action of the acid is a compound represented by a general formula (II): 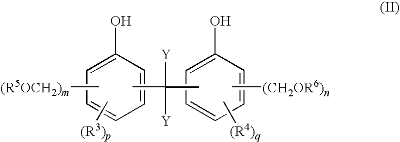
wherein, two Y each independently represent a hydrogen atom or an alkyl group having 1 to 10 carbon atoms and may include an oxygen atom or a fluorine atom, R³ to R⁶ each independently represent a hydrogen atom or a monovalent organic group, m and n each independently represent an integer of 1 to 3, and p and q each independently represent an integer of 0 to 4.

4. The negative-type photosensitive resin composition according to claim 1, wherein the crosslinking agent (c) capable of crosslinking or polymerizing by the action of the acid is a compound represented by a general formula (III): 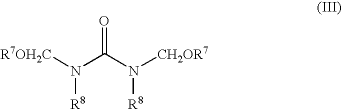
wherein, R⁷ and R⁸ each independently represent a hydrogen atom or a monovalent organic group.

5. The negative-type photosensitive resin composition according to claim 1, wherein the heat resistant polymer (a) is polyimide, polyoxazole or a precursor thereof.

6. A method for producing a pattern comprising a step of applying and drying the negative-type photosensitive resin composition according to claim 1 on a support substrate, a step of exposing a photosensitive resin film obtained from the step of drying, a step of heating the photosensitive resin film after the exposure, a step of developing the photosensitive resin film after the heating using an alkaline aqueous solution, and a step of thermally treating the photosensitive resin film after the development.

7. An electronic part having an electronic device having a layer of a pattern obtained by the method according to claim 6, wherein the layer of the pattern is provided as an interlayer insulation film layer and/or a surface protection film layer in the electronic device.

8. The negative-type photosensitive resin composition according to claim 2, wherein the heat resistant polymer (a) is polyimide, polyoxazole or a precursor thereof.

9. The negative-type photosensitive resin composition according to claim 3, wherein the heat resistant polymer (a) is polyimide, polyoxazole or a precursor thereof.

10. The negative-type photosensitive resin composition according to claim 4, wherein the heat resistant polymer (a) is polyimide, polyoxazole or a precursor thereof.

11. A method for producing a pattern comprising a step of applying and drying the negative-type photosensitive resin composition according to claim 2 on a support substrate, a step of exposing a photosensitive resin film obtained from the step of drying, a step of heating the photosensitive resin film after the exposure, a step of developing the photosensitive resin film after the heating using an alkaline aqueous solution, and a step of thermally treating the photosensitive resin film after the development.

12. A method for producing a pattern comprising a step of applying and drying the negative-type photosensitive resin composition according to claim 3 on a support substrate, a step of exposing a photosensitive resin film obtained from the step of drying, a step of heating the photosensitive resin film after the exposure, a step of developing the photosensitive resin film after the heating using an alkaline aqueous solution, and a step of thermally treating the photosensitive resin film after the development.

13. A method for producing a pattern comprising a step of applying and drying the negative-type photosensitive resin composition according to claim 4 on a support substrate, a step of exposing a photosensitive resin film obtained from the step of drying, a step of heating the photosensitive resin film after the exposure, a step of developing the photosensitive resin film after the heating using an alkaline aqueous solution, and a step of thermally treating the photosensitive resin film after the development.

14. A method for producing a pattern comprising a step of applying and drying the negative-type photosensitive resin composition according to claim 5 on a support substrate, a step of exposing a photosensitive resin film obtained from the step of drying, a step of heating the photosensitive resin film after the exposure, a step of developing the photosensitive resin film after the heating using an alkaline aqueous solution, and a step of thermally treating the photosensitive resin film after the development.
